(19) United States
(12) Patent Application Publication
(10) Pub. No.: US 2026/0114315 A1
(43) Pub. Date: Apr. 23, 2026

(54) SEMICONDUCTOR PACKAGE

(71) Applicant: SAMSUNG ELECTRONICS CO., LTD., Suwon-si (KR)

(72) Inventor: Hyeonkyu HA, Suwon-si (KR)

(73) Assignee: SAMSUNG ELECTRONICS CO., LTD., Suwon-si (KR)

(21) Appl. No.: 19/221,920

(22) Filed: May 29, 2025

(30) Foreign Application Priority Data
Oct. 18, 2024 (KR) 10-2024-0143251

(51) Int. Cl. H01L 23/31; H01L 23/00; H01L 25/07

(52) U.S. Cl. CPC H10W 74/117; H10W 90/00; H10W 72/325; H10W 72/351; H10W 72/354; H10W 90/732; H10W 90/792

(57) ABSTRACT

A semiconductor package including a substrate, a chip stack stacked on a top surface of the substrate, and a mold layer provided on the top surface of the substrate and the chip stack is provided. The chip stack include a first chip having a first region provided with chip pads and second regions provided at a first side and a second side of the first region. The chip pads of the first chip may be bonded to substrate pads of the substrate to form a single object. Each of the second regions of the first chip may be spaced apart from the top surface of the substrate in a direction perpendicular to the top surface of the substrate. The mold layer may fill a space between each of the second regions and the top surface of the substrate.

This U.S. non-provisional patent application is based on claims priority under 35 U.S.C. §119 to Korean Patent Application No. 10-2024-0143251, filed on October 18, 2024, in the Korean Intellectual Property Office, the entire contents of which are hereby incorporated by reference.

### BACKGROUND

The disclosure relates to a semiconductor package and a method of fabricating the same, and in particular, to a stack-type semiconductor package, in which a plurality of semiconductor chips are stacked on a substrate, and a method of fabricating the same.

Due to the rapid development of the electronic industry and the increase in the diversity of user needs, electronic devices are required to have reduced sizes and more functionality. Accordingly, semiconductor devices used in the electronic devices are also required to have reduced sizes and are configured to perform more functions. In order to satisfy this demand, a semiconductor package technology has been proposed in which a plurality of vertically stacked semiconductor chips are connected using through-substrate vias (TSVs).

### SUMMARY

Aspects of the disclosure provide a semiconductor package with improved structural reliability.

According to an aspect of the disclosure, there is provided a semiconductor package, including: a first semiconductor substrate including a top surface and a bottom surface; a chip stack stacked on the top surface of the first semiconductor substrate, the chip stack including a plurality of semiconductor chips; and a mold layer provided on the top surface of the first semiconductor substrate and on the chip stack, wherein a first semiconductor chip, among the plurality of semiconductor chips, includes: a first region provided with a plurality of chip pads; and a plurality of second regions provided at a first side and a second side of the first region, wherein each of the plurality of chip pads of the first semiconductor chip is bonded to one of a plurality of substrate pads of the first semiconductor substrate, the plurality of chip pads and the plurality of substrate pads are formed of a same metallic material to form a single object, each of the plurality of second regions of the first semiconductor chip is spaced apart from the top surface of the first semiconductor substrate in a first direction perpendicular to the top surface of the first semiconductor substrate, and the mold layer fills a space between each of the plurality of second regions and the top surface of the first semiconductor substrate.

According to another aspect of the disclosure, there is provided a semiconductor package, including: a first semiconductor substrate including a top surface and a bottom surface; a chip stack stacked on the top surface of the first semiconductor substrate, the chip stack including a plurality of semiconductor chips; and a mold layer provided on the first semiconductor substrate and on the chip stack, wherein a first semiconductor chip, among the plurality of semiconductor chips, includes: a first region provided with a plurality of chip pads; and a plurality of second regions provided at a first side and a second side of the first region, wherein each of the plurality of chip pads of the first semiconductor chip is bonded to one of a plurality of substrate pads of the first semiconductor substrate, the plurality of chip pads and the plurality of substrate pads are formed of a same metallic material to form a single object, each of the plurality of second regions of the first semiconductor chip is spaced apart from the top surface of the first semiconductor substrate in a first direction perpendicular to the top surface of the first semiconductor substrate, wherein the mold layer includes: a first mold layer filling a space between each of the plurality of second regions and the top surface of the first semiconductor substrate; and a second mold layer provided on the top surface of the first semiconductor substrate, the chip stack, and the first mold layer.

According to another aspect of the disclosure, there is provided a semiconductor package, including: a package substrate; an interposer substrate on the package substrate; a first semiconductor substrate provided on the interposer substrate, the first semiconductor substrate comprising a top surface and a bottom surface; a chip stack stacked on the top surface of t first semiconductor substrate, the chip stack comprising a plurality of semiconductor chips; and a mold layer provided on the top surface of the first semiconductor substrate and on the chip stack, wherein a first semiconductor chip, among the plurality of semiconductor chips: a first region provided with a plurality of chip pads; and a plurality of second regions provided at a first side and a second side of the first region, wherein each of the plurality of chip pads of the first semiconductor chip is bonded to one of a plurality of substrate pads of the first semiconductor substrate, the plurality of chip pads and the plurality of substrate pads are formed of a same metallic material to form a single object, each of the plurality of second regions of the first semiconductor chip is spaced apart from the top surface of the first semiconductor substrate in a first direction perpendicular to the top surface of the first semiconductor substrate, and the mold layer fills a space between each of the plurality of second regions and the top surface of the first semiconductor substrate.

### BRIEF DESCRIPTION OF DRAWINGS

FIG. 1 is a plan view illustrating a semiconductor package according to an embodiment of the disclosure.

FIG. 2 is a sectional view of the semiconductor package taken along a line A-A’ of FIG. 1.

FIG. 3 is an enlarged view illustrating a first semiconductor substrate and a first semiconductor chip according to an embodiment of the disclosure.

FIGS. 4 and 5 are sectional views taken along the line A-A’ of FIG. 1 to illustrate a method of fabricating a semiconductor package, according to an embodiment of the disclosure.

FIG. 6 is a sectional view of the semiconductor package taken along the line A-A’ of FIG. 1.

FIG. 7 is a sectional view, which is taken along the line A-A’ of FIG. 1 to illustrate a method of fabricating a semiconductor package, according to an embodiment of the disclosure.

FIG. 8 is a plan view illustrating a semiconductor package according to an embodiment of the disclosure.

FIG. 9 is a sectional view of the semiconductor package taken along a line A-A’ of FIG. 8.

FIG. 10 is a sectional view illustrating a semiconductor package according to an embodiment of the disclosure, taken along the line A-A’ of FIG. 8.

### DETAILED DESCRIPTION

To fully understand the configuration and effects of the disclosure, some embodiments of the disclosure will be described with reference to the accompanying drawings. However, the disclosure is not limited to the embodiments disclosed below and may be implemented in various shapes and with different modifications. The purpose of the descriptions of the embodiments is to ensure a comprehensive disclosure of the disclosure and to fully convey the scope of the invention to those skilled in the technical field to which the disclosure pertains.

In the disclosure, when a particular element is described as being “on” another element, it may mean that the particular element is directly formed on the other element or that a third element may be interposed between them. Furthermore, in the drawings, the thicknesses of the elements may be exaggerated to effectively explain the technical content. Throughout the specification, elements indicated by the same reference numerals represent the same elements.

In the disclosure, unless otherwise specified, terms expressed in the singular form may also include the plural. Additionally, unless otherwise specified, the term “A or B” may mean “including A, or including B, or including both A and B.” The terms “comprises” and/or “comprising,” as used in the disclosure, do not exclude the presence or addition of one or more other elements.

In the disclosure, unless otherwise defined, a particle diameter may refer to an average particle diameter. For example, the particle diameter refers to the average particle diameter D50, which is the diameter of particles at 50 volume% cumulative in the particle size distribution. The average particle diameter D50 can be measured by methods widely known to those skilled in the art. According to an embodiment, the average particle diameter D50 can be measured using a particle size analyzer or by analyzing images from a transmission electron microscope (TEM) or a scanning electron microscope (SEM). According to another embodiment, the measurement can be performed using a dynamic light-scattering method. In this method, data analysis is conducted after counting the number of particles in each particle size range, and the average particle diameter D50 is calculated from the results. According to another embodiment, a laser diffraction method may be used to measure the average particle diameter D50. For example, in the laser diffraction method, the particles to be measured are dispersed in a dispersion medium and then introduced into a commercially available laser diffraction particle size measurement device (e.g., Microtrac MT 3000). For example, ultrasonic waves of about 28 kHz are applied at an output of 60 W, and the average particle diameter D50 is calculated based on the 50% point in the particle size distribution measured by the device.

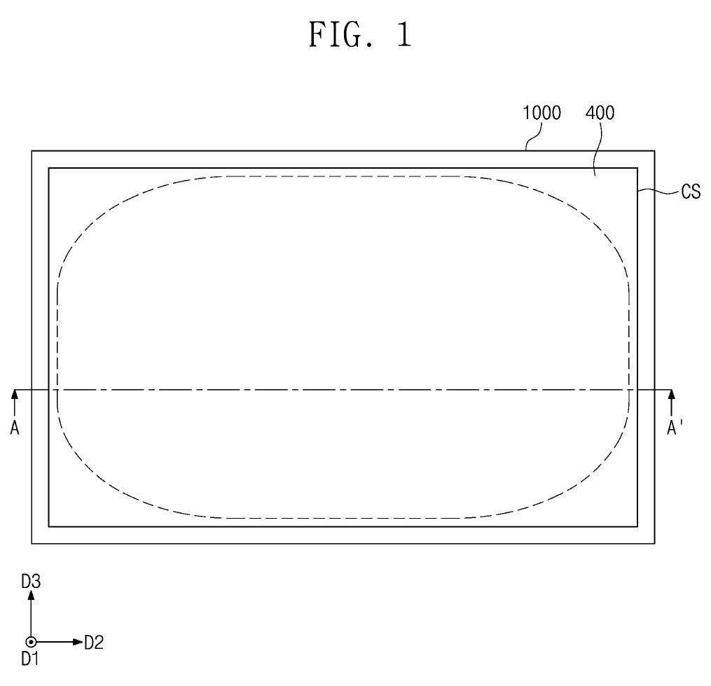

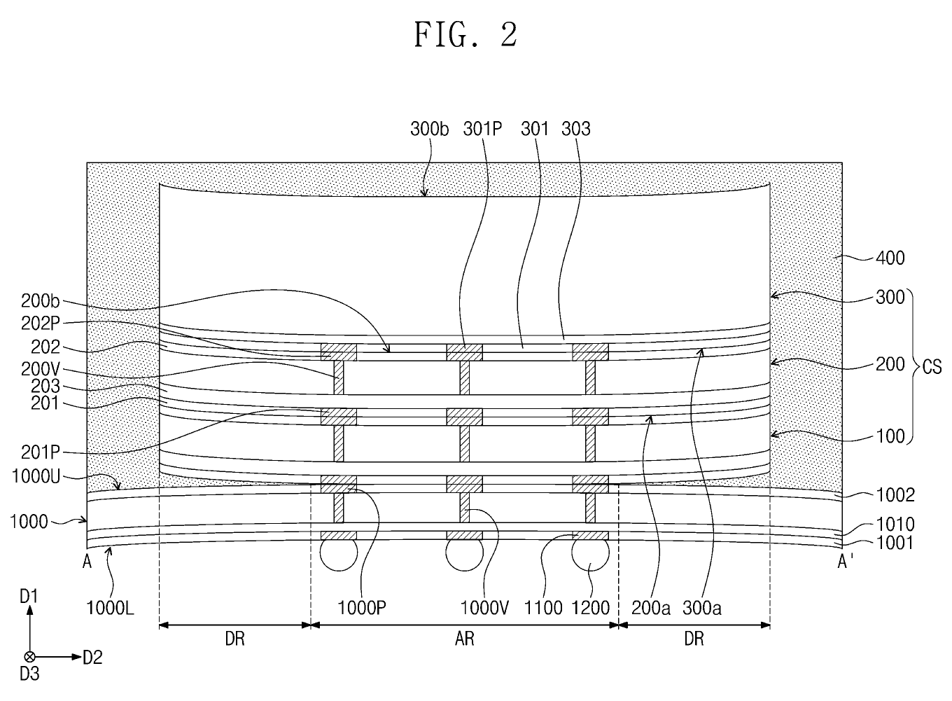

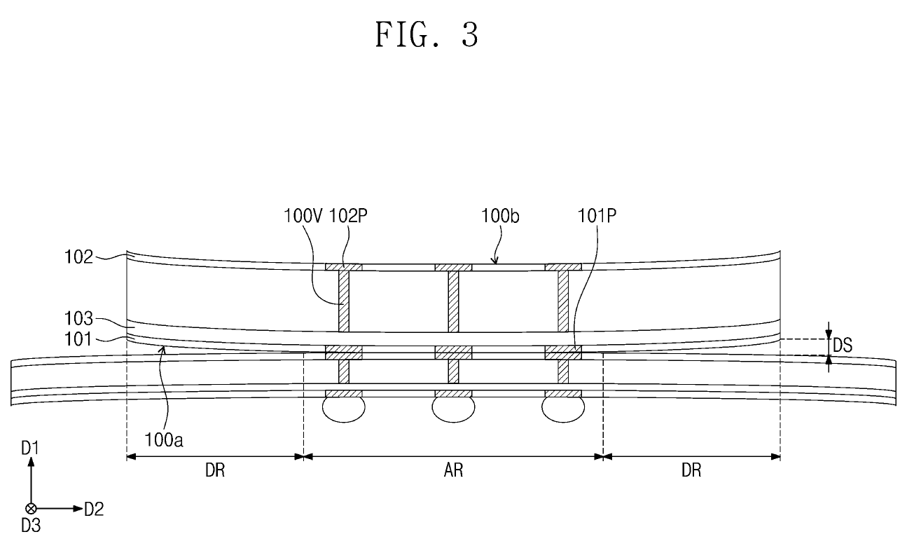

FIG. 1 is a plan view illustrating a semiconductor package according to an embodiment of the disclosure. FIG. 2 is a sectional view of the semiconductor package taken along a line A-A’ of FIG. 1. FIG. 3 is an enlarged view illustrating a first semiconductor chip according to an embodiment of the disclosure.

Referring to FIGS. 1 and 2, a first semiconductor substrate 1000 may be provided. The first semiconductor substrate 1000 may include a top surface 1000U and a bottom surface 1000L, which are opposite to each other. The first semiconductor substrate 1000 may include an integrated circuit. For example, the integrated circuit may be provide in the first semiconductor substrate 1000 and/or on a surface of the first semiconductor substrate 1000. The first semiconductor substrate 1000 may be a buffer semiconductor chip including an electronic device. For example, the electronic device may include, but is not limited to, a transistor. In an embodiment, the first semiconductor substrate 1000 may be a wafer-level die, which is formed of a semiconductor material. The semiconductor material may include, but is not limited to, silicon (Si).

A first circuit layer 1010 may be provided on the bottom surface 1000L of the first semiconductor substrate 1000. The first circuit layer 1010 may include an integrated circuit. The first circuit layer 1010 may include, but is not limited to, a memory circuit, a logic circuit, or combinations thereof. For example, the bottom surface 1000L of the first semiconductor substrate 1000 may be referred to as an active surface. An electronic device (e.g., a transistor), an insulating pattern, and an interconnection pattern may be provided on the bottom surface 1000L of the first semiconductor substrate 1000.

The first semiconductor substrate 1000 may include a penetration via 1000V penetrating the first semiconductor substrate 1000. The penetration via 1000V may be provided to penetrate the first semiconductor substrate 1000 in a first direction D1. The first direction D1 may be perpendicular to the top surface 1000U of the first semiconductor substrate 1000. In an embodiment, a plurality of penetration vias 1000V may be provided. According to an embodiment, an insulating layer may be provided on the penetration via 1000V. For example, in a case in which the penetration via 1000V have to be insulated, the insulation layer may be provided to enclose the penetration via 1000V. For example, the insulating layer may be formed of or include at least one of silicon oxide (SiO), silicon nitride (SiN), silicon oxynitride (SiON), or low-k dielectric materials. However, the disclosure is not limited thereto

According to an embodiment, substrate pads 1000P may be provided on the top surface 1000U of the first semiconductor substrate 1000. For example, the substrate pads 1000P may be provided adjacent to the top surface 1000U of the first semiconductor substrate 1000. Each of the substrate pads 1000P may be electrically connected to the penetration via 1000V. Each of the substrate pads 1000P may be formed of or include at least one of copper (Cu), aluminum (Al), or nickel (Ni). However, the disclosure is not limited thereto.

An upper insulating layer 1002 may be provided on the top surface 1000U of the first semiconductor substrate 1000. For example, the upper insulating layer 1002 may be provided adjacent to the top surface 1000U of the first semiconductor substrate 1000. The upper insulating layer 1002 may be extended into a region between the substrate pads 1000P. For example, the upper insulating layer 1002 may cover side surfaces of the substrate pads 1000P. The upper insulating layer 1002 may be formed of or include at least one of silicon oxide (SiO), silicon nitride (SiN), silicon oxynitride (SiON), or silicon carbon nitride (SiCN). However, the disclosure is not limited thereto. The upper insulating layer 1002 may be provided to expose the topmost surfaces of the substrate pads 1000P. The top surface 1000U of the first semiconductor substrate 1000 may correspond to a top surface of the upper insulating layer 1002.

Connection pads 1100 may be provided on the bottom surface 1000L of the first semiconductor substrate 1000. The connection pads 1100 may be electrically connected to the first circuit layer 1010. Each of the connection pads 1100 may be formed of or include at least one of copper (Cu), aluminum (Al), or nickel (Ni). However, the disclosure is not limited thereto.

The first semiconductor substrate 1000 may further include a lower insulating layer 1001. The lower insulating layer 1001 may be provided adjacent to the bottom surface 1000L of the first semiconductor substrate 1000. For example, the lower insulating layer 1001 may be provided on the bottom surface 1000L of the first semiconductor substrate 1000. The lower insulating layer 1001 may cover the first circuit layer 1010 and the connection pads 1100. The first circuit layer 1010 may be protected by the lower insulating layer 1001. The lower insulating layer 1001 may expose the bottommost surfaces of the connection pads 1100. The lower insulating layer 1001 may be formed of or include at least one of silicon oxide (SiO), silicon nitride (SiN), silicon oxynitride (SiON), or silicon carbon nitride (SiCN). However, the disclosure is not limited thereto. The bottom surface 1000L of the first semiconductor substrate 1000 may correspond to a bottom surface of the lower insulating layer 1001.

Outer terminals 1200 may be provided on the connection pads 1100. The outer terminals 1200 may be electrically connected to the first circuit layer 1010 and the penetration via 1000V through the connection pads 1100. The outer terminals 1200 may be formed of or include at least one of tin (Sn), silver (Ag), copper (Cu), nickel (Ni), bismuth (Bi), indium (In), antimony (Sb), cerium (Ce), or alloys thereof. However, the disclosure is not limited thereto.

An edge portion of the first semiconductor substrate 1000 may be bent toward the bottom surface 1000L of the first semiconductor substrate 1000. The first semiconductor substrate 1000 may be deformed in a crying warpage shape.

A chip stack CS may be provided on the first semiconductor substrate 1000. The chip stack CS may include a plurality of semiconductor chips 100, 200, and 300. The semiconductor chips 100, 200, and 300 may be of the same kind and may be memory chips. In an embodiment, each of the semiconductor chips 100, 200, and 300 may be a volatile memory semiconductor chip (e.g., a dynamic random access memory (DRAM) chip or a static random access memory (SRAM) chip). In an embodiment, each of the semiconductor chips 100, 200, and 300 may be a nonvolatile memory semiconductor chip (e.g., a FLASH memory chip, a phase-change random access memory (PRAM) chip, a magnetic random access memory (MRAM) chip, a ferroelectric random access memory (FeRAM) chip, or a resistive random access memory (RRAM) chip). However, the disclosure is not limited thereto, and as such, according to another embodiment, the semiconductor chips 100, 200, and 300 may be of a different kind.

The chip stack CS may include a first semiconductor chip 100, which is directly connected to the first semiconductor substrate 1000, at least one second semiconductor chip 200 stacked on the first semiconductor chip 100, and a third semiconductor chip 300 provided on the second semiconductor chip 200. The first to the third semiconductor chips 100, 200, and 300 may be sequentially stacked on the first semiconductor substrate 1000.

Although, FIG. 2 illustrates the semiconductor package including three semiconductor chips, the disclosure is not limited thereto. As such, according to an embodiment, the number of the semiconductor chips in the semiconductor package may be greater or fewer than three and is not limited to a specific value. In an embodiment, the chip stack CS may have a high bandwidth memory (HBM) structure.

Referring to FIG. 3, the first semiconductor chip 100 may include a first region AR and second regions DR. The second regions DR are provided on a first side and a second side of the first region AR. For example, the second regions DR are provided on both sides of the first region AR. Each of the second regions DR may be provided at an edge portion of the first semiconductor chip 100. The second regions DR may be spaced apart from each other in a second direction D2, with the first region AR interposed between the second regions DR.

The second direction D2 may be parallel to the top surface 1000U of the first semiconductor substrate 1000 and may be perpendicular to the first direction D1. The first region AR may be interposed between the second regions DR.

Each of the second regions DR may be spaced apart from the top surface 1000U of the first semiconductor substrate 1000 in the first direction D1. The second regions DR may have a warpage structure in the first direction D1. In an embodiment, the first semiconductor chip 100 may have the warpage structure that is increasingly spaced apart from the top surface 1000U of the first semiconductor substrate 1000 in the first direction D1. A first distance DS between each of the second regions DR and the top surface 1000U in the first direction D1 may increase at a position closer to the edge portion of the first semiconductor substrate 1000. In an embodiment, the first distance DS may have the largest value at a corner portion CP of the first semiconductor chip 100. Referring to FIG. 1, the corner portion CP may be a corner that is defined by two adjacent side surfaces of the first semiconductor chip 100. In an embodiment, the first distance DS may decrease as a distance to the first region AR decreases.

Referring to FIG. 3, first chip pads 101P may be provided on the first region AR. The first chip pads 101P may be electrically connected to the substrate pads 1000P of the first semiconductor substrate 1000.

At an interface between the first semiconductor chip 100 and the first semiconductor substrate 1000, the substrate pads 1000P of the first semiconductor substrate 1000 may be bonded to the first chip pads 101P of the first semiconductor chip 100. Here, the substrate pads 1000P and the first chip pads 101P may form an inter-metal hybrid bonding structure. According to an embodiment in the disclosure, the hybrid bonding structure may mean a bonding structure that is formed by two materials, which are of the same kind and are fused at an interface between the two materials.

In an embodiment, each of the substrate pads 1000P and each of the first chip pads 101P, which are bonded to each other, may form a continuous structure, and there may be no visible or observable interface between each of the substrate pads 1000P and each of the first chip pads 101P. In an embodiment, the substrate pads 1000P and the first chip pads 101P may be formed of the same material, and in this case, there may be no interface between each of the substrate pads 1000P and each of the first chip pads 101P. For example, each of the substrate pads 1000P and each of the first chip pads 101P may be provided as a single element. In an embodiment, each of the substrate pads 1000P and each of the first chip pads 101P may be bonded to form a single object.

First chip penetration vias 100V may be provided to penetrate the first semiconductor chip 100 in the first direction D1. The first chip penetration vias 100V may be provided on the first region AR. The first chip penetration vias 100V may be electrically connected to the first chip pads 101P.

The second regions DR may be electrically disconnected from the first semiconductor substrate 1000. For example, the second regions DR may not include the first chip pads 101P and the first chip penetration vias 100V.

The first semiconductor chip 100 may include a first surface 100a and a second surface 100b, which are opposite to each other. The first surface 100a may face the top surface 1000U of the first semiconductor substrate 1000.

The first chip pads 101P may be provided adjacent to the first surface 100a of the first semiconductor chip 100. The first insulating layer 101 may be provided to be adjacent to the first surface 100a and may be extended into a region between the first chip pads 101P. At least a portion of the first insulating layer 101 may be in contact with the upper insulating layer 1002. The first insulating layer 101 on the first region AR may be in contact with the upper insulating layer 1002. The first insulating layer 101 on the second regions DR may be spaced apart from the upper insulating layer 1002 in the first direction D1.

The first insulating layer 101 may be formed of or include the same material as the upper insulating layer 1002 of the first semiconductor substrate 1000, and the first insulating layer 101 and the upper insulating layer 1002 may be in contact with each other to form a single object. In an embodiment, the first insulating layer 101 may be formed of or include at least one of silicon oxide (SiO), silicon nitride (SiN), silicon oxynitride (SiON), or silicon carbon nitride (SiCN). However, the disclosure is not limited thereto.

In an embodiment, the upper insulating layer 1002 of the first semiconductor substrate 1000 may be bonded to the first insulating layer 101 of the first semiconductor chip 100. For example, a an interface between the first semiconductor substrate 1000 and the first semiconductor chip 100, the upper insulating layer 1002 of the first semiconductor substrate 1000 may be bonded to the first insulating layer 101 of the first semiconductor chip 100. Here, the upper insulating layer 1002 and the first insulating layer 101 may form a hybrid bonding structure, For example, the hybrid bonding structure may be formed or may include, but is not limited to, oxide, nitride, or oxynitride. In an embodiment, the upper insulating layer 1002 and the first insulating layer 101 may be formed of the same material, and in this case, there may be no interface between the upper insulating layer 1002 and the first insulating layer 101. For example, the upper insulating layer 1002 and the first insulating layer 101 may be bonded to form a single object. However, the disclosure is not limited to this example. In an embodiment, the upper insulating layer 1002 and the first insulating layer 101 may be formed of different materials and may not have a continuous structure, and in this case, there may be a visible interface between the upper insulating layer 1002 and the first insulating layer 101.

According to an embodiment, a second circuit layer 103 may be provided on the first insulating layer 101. The second circuit layer 103 may include, for example, a memory circuit. In an embodiment, the first surface 100a of the first semiconductor chip 100 may be referred to as an active surface.

The second circuit layer 103 may include an electronic device, an insulating pattern, and an interconnection pattern, which are provided on the first region AR. The electronic device may include, but is not limited to, a transistor. The second circuit layer 103 may be electrically connected to the first chip penetration vias 100V. The first chip pads 101P may be electrically connected to the second circuit layer 103. In an embodiment, the second circuit layer 103 may not include an electronic device (e.g., a transistor), an insulating pattern, and an interconnection pattern, on the second regions DR.

Second chip pads 102P may be provided adjacent to the second surface 100b. The second chip pads 102P may be electrically connected to the first chip penetration vias 100V. The second chip pads 102P may be arranged to correspond to the first chip pads 101P. The second chip pads 102P may be provided on the first region AR and may not be provided on the second regions DR. The second chip pads 102P may be electrically connected to the second circuit layer 103 and the first chip pads 101P through the first chip penetration vias 100V.

A second insulating layer 102 may be provided to be adjacent to the second surface 100b and may be extended into a space between the second chip pads 102P. The second insulating layer 102 may be provided to expose the topmost surfaces of the second chip pads 102P. In an embodiment, the second insulating layer 102 may be formed of or include at least one of silicon oxide (SiO), silicon nitride (SiN), silicon oxynitride (SiON), or silicon carbon nitride (SiCN). However, the disclosure is not limited thereto. In an embodiment, the second insulating layer 102 may be formed of or include the same material as the first insulating layer 101.

Referring back to FIG. 2, the second semiconductor chip 200 may have substantially the same structure as the first semiconductor chip 100. In an embodiment, the second semiconductor chip 200 may include a third surface 200a facing the first semiconductor substrate 1000 and a fourth surface 200b opposite to the third surface 200a. Third chip pads 201P and a third insulating layer 201 may be provided to be adjacent to the third surface 200a. The third insulating layer 201 may be extended into a region between the third chip pads 201P to cover side surfaces of the third chip pads 201P. The third insulating layer 201 may be provided to expose the bottommost surfaces of the third chip pads 201P. A third circuit layer 203 may be provided to be adjacent to the third surface 200a, and second chip pad vias 200V may be provided to penetrate the second semiconductor chip 200.

Fourth chip pads 202P and a fourth insulating layer 202 may be provided adjacent to the fourth surface 200b. The fourth insulating layer 202 may be extended into a region between the fourth chip pads 202P and may cover the side surfaces of the fourth chip pads 202P. The fourth insulating layer 202 may be provided to expose the topmost surfaces of the fourth chip pads 202P.

The third semiconductor chip 300 may have a structure that is substantially similar to the first semiconductor chip 100. The third semiconductor chip 300 may include a fifth surface 300a facing the first semiconductor substrate 1000 and a sixth surface 300b opposite to the fifth surface 300a. Fifth chip pads 301P may be provided to be adjacent to the fifth surface 300a, and a fifth insulating layer 301 may be provided to extend into a region between the fifth chip pads 301P. The fifth insulating layer 301 may be provided to cover side surfaces of the fifth chip pads 301P and to expose the bottommost surfaces of the fifth chip pads 301P. In an embodiment, the third semiconductor chip 300 may not have a via plug, a rear pad, and an insulating layer. However, the disclosure is not limited to this example. In an embodiment, the third semiconductor chip 300 may include at least one of the via plug, the rear pad, and the insulating layer.

A fourth circuit layer 303 may be provided adjacent to the fifth surface 300a of the third semiconductor chip 300. The fifth surface 300a of the third semiconductor chip 300 may be referred to as an active surface. The third semiconductor chip 300 may have a thickness that is larger than the first and second semiconductor chips 100 and 200.

The first and second semiconductor chips 100 and 200 may be in contact with each other. The second chip pads 102P of the first semiconductor chip 100 may be in contact with the third chip pads 201P of the second semiconductor chip 200. The second chip pads 102P and the third chip pads 201P may form an inter-metal hybrid bonding structure. The second insulating layer 102 of the first semiconductor chip 100 and the third insulating layer 201 of the second semiconductor chip 200 may be in contact with each other. The second insulating layer 102 and the third insulating layer 201 may form a hybrid bonding structure of oxide, nitride, oxynitride, or carbon nitride.

The second semiconductor chip 200 and the third semiconductor chip 300 may be in contact with each other. The fourth chip pads 202P of the second semiconductor chip 200 may be in contact with the fifth chip pads 301P of the third semiconductor chip 300. The fourth chip pads 202P and the fifth chip pads 301P may form an inter-metal hybrid bonding structure. The fourth insulating layer 202 of the second semiconductor chip 200 and the fifth insulating layer 301 of the third semiconductor chip 300 may be in contact with each other. The fourth and fifth insulating layers 202 and 301 may form a hybrid bonding structure of oxide, nitride, oxynitride, or carbon nitride. The first chip pads 101P may be referred to as first front pads 101P, the third chip pads 201P may be referred to as second front pads 201P, and the fifth chip pads 301P may be referred to as third front pads 301P. The second chip pads 102P may be referred to as first rear pads 102P, and the fourth chip pads 202P may be referred to as second rear pads 302P.

Referring back to FIGS. 1 and 2, a mold layer 400 may be provided on the first semiconductor substrate 1000 and the chip stack CS. For example, the mold layer 400 may cover the top surface 1000U of the first semiconductor substrate 1000 and the chip stack CS. The mold layer 400 may be provided to fill a space between each of the second regions DR of the first semiconductor chip 100 and the top surface 1000U of the first semiconductor substrate 1000.

The mold layer 400 may be provided to on a side surface of the chip stack CS and on the top surface 1000U of the first semiconductor substrate 1000. For example, the mold layer 400 may be provided to cover a side surface of the chip stack CS and the top surface 1000U of the first semiconductor substrate 1000 and may be extended into a space between each of the second regions DR of the first semiconductor chip 100 and the top surface 1000U of the first semiconductor substrate 1000. The mold layer 400 may be in contact with the first insulating layer 101 on the second regions DR of the first semiconductor chip 100 and may be in contact with the upper insulating layer 1002 of the first semiconductor substrate 1000. The mold layer 400 may cover the corner portion CP of the first semiconductor chip 100 and the top surface 1000U of the first semiconductor substrate 1000.

The mold layer 400 may be formed of or include at least one of epoxy molding compounds, resins, and polyimide. However, the disclosure is not limited thereto. For example, the mold layer 400 may further include a filler. An average particle diameter of the filler may be less than or equal to 10 μm. The average particle diameter of the filler may range from 0.5 μm to 3 μm.

In an example case in which the average particle diameter of the filler is larger than 3 μm, the mold layer 400 may not fill a space between each of the second regions DR of the first semiconductor chip 100 and the top surface 1000U of the first semiconductor substrate 1000. In an example case in which the average particle diameter of the filler is smaller than 0.5 μm, an agglomeration phenomenon may occur between the fillers in the semiconductor package.

In an embodiment, the mold layer 400 may be provided to fill a space between each of the second regions DR and the top surface 1000U of the first semiconductor substrate 1000. The mold layer 400 may be formed to fill a space between the second regions DR and the first semiconductor substrate 1000, and an empty space (e.g., a void) may not be formed in the space between the second regions DR and the first semiconductor substrate 1000. Thus, due to a difference in thermal expansion coefficient between the empty space and the mold layer 400, it may be possible to prevent the mold layer 400 from being damaged. For example, it may be possible to prevent the mold layer 400 from being damaged by contraction or expansion caused by heat generated by the semiconductor package. For example, the heat may be generated based on an operation of the semiconductor package. For example, it may be possible to prevent the mold layer 400 from being damaged by the contraction or expansion caused by heat generated during an operation of the semiconductor package. Thus, the structural reliability of the semiconductor package may be improved.

Furthermore, the mold layer 400 may be in contact with the upper insulating layer 1002 of the first semiconductor substrate 1000. The mold layer 400 may be in contact with the upper insulating layer 1002 of the first semiconductor substrate 1000, between each of the second regions DR and the top surface 1000U of the first semiconductor substrate 1000. Thus, the mold layer 400 may prevent the upper insulating layer 1002 from being delaminated by the warpage structure of the first semiconductor substrate 1000. Accordingly, it may be possible to improve the structural reliability of the semiconductor package.

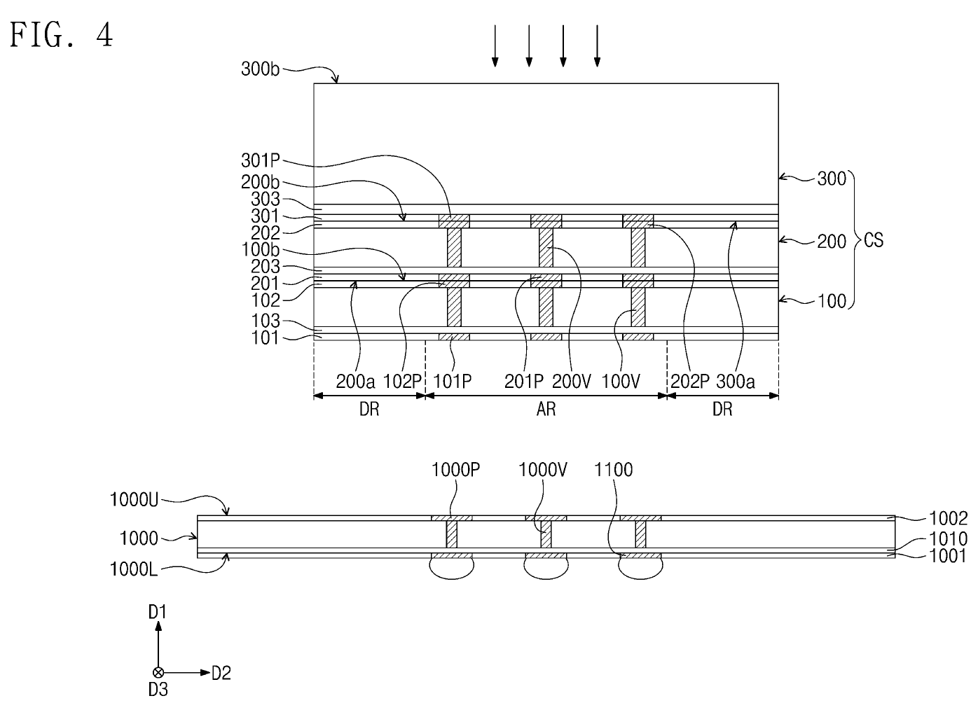

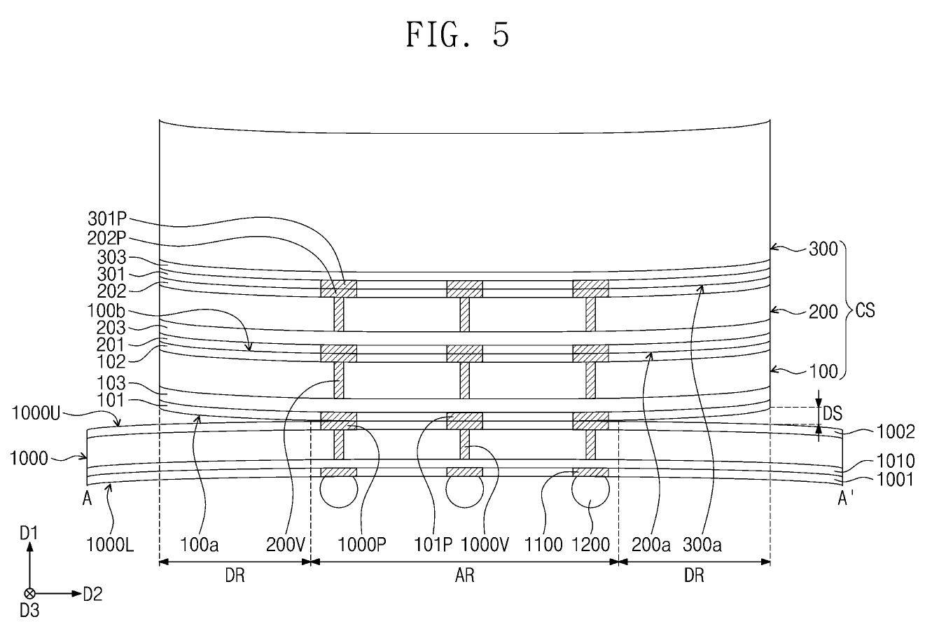

FIGS. 4 and 5 are sectional views taken along the line A-A’ of FIG. 1 to illustrate a method of fabricating a semiconductor package, according to an embodiment of the disclosure. For concise description, an element previously described with reference to FIGS. 1 to 3 may be identified by the same reference number without repeating an overlapping description thereof.

Referring to FIG. 4, the chip stack CS may be provided on the top surface 1000U of the first semiconductor substrate 1000. The chip stack CS may include the first semiconductor chip 100, the second semiconductor chip 200 on the first semiconductor chip 100, and the third semiconductor chip 300 on the second semiconductor chip 200.

The first semiconductor chip 100 may include the first region AR and the second regions DR, which are placed at both sides of the first region AR. Each of the second regions DR may be an edge portion of the first semiconductor chip 100. The second regions DR may be spaced apart from each other in the second direction D2, with the first region AR interposed therebetween.

The first chip pads 101P may be provided on the first region AR. The first chip penetration vias 100V may be provided to penetrate the first semiconductor chip 100 in the first direction D1. The first chip penetration vias 100V may be provided on the first region AR. The first chip penetration vias 100V may be electrically connected to the first chip pads 101P.

The first semiconductor chip 100 may include a first surface 100a and a second surface 100b, which are opposite to each other. The first surface 100a may face the top surface 1000U of the first semiconductor substrate 1000. The first chip pads 101P may be provided to be adjacent to the first surface 100a. The first insulating layer 101 may be provided to be adjacent to the first surface 100a and may be extended into a space between the first chip pads 101P.

The second circuit layer 103 may be provided to be adjacent to the first surface 100a of the first semiconductor chip 100. In an embodiment, the second circuit layer 103 may include a memory circuit. The second circuit layer 103 may include an electronic device (e.g., a transistor), an insulating pattern, and an interconnection pattern, which are provided on the first region AR. The first chip pads 101P may be electrically connected to the second circuit layer 103. In an embodiment, the second circuit layer 103 may not include an electronic device (e.g., a transistor), an insulating pattern, and an interconnection pattern, on the second regions DR.

The second chip pads 102P may be provided to be adjacent to the second surface 100b. The second chip pads 102P may be electrically connected to the first chip penetration vias 100V. In an embodiment, the second chip pads 102P may be arranged to correspond to the first chip pads 101P. The second chip pads 102P may be provided on the first region AR and may not be provided on the second regions DR. The second chip pads 102P may be electrically connected to the second circuit layer 103 and corresponding ones of the first chip pads 101P through the first chip penetration vias 100V.

The second insulating layer 102 may be provided to be adjacent to the second surface 100b and may be extended into a region between the second chip pads 102P. In an embodiment, the second insulating layer 102 may include the same material as the first insulating layer 101.

The second semiconductor chip 200 may have substantially the same structure as the first semiconductor chip 100. In an embodiment, the second semiconductor chip 200 may include a third surface 200a facing the first semiconductor substrate 1000 and a fourth surface 200b opposite to the third surface 200a. The third chip pads 201P may be provided to be adjacent to the third surface 200a, and the third insulating layer 201 may be provided into a region between the third chip pads 201P. The third circuit layer 203 may be provided on the third surface 200a, and the second chip pad vias 200V may be provided to penetrate the second semiconductor chip 200. The fourth chip pads 202P may be provided to be adjacent to the fourth surface 200b, and the fourth insulating layer 202 may be extended into a region between the fourth chip pads 202P.

The third semiconductor chip 300 may have a structure that is substantially similar to the first semiconductor chip 100. For example, the third semiconductor chip 300 may include the fifth surface 300a facing the first semiconductor substrate 1000 and the sixth surface 300b opposite to the fifth surface 300a. The fifth chip pads 301P may be provided to be adjacent to the fifth surface 300a, and the fifth insulating layer 301 may be extended into a space between the fifth chip pads 301P.

The second semiconductor chip 200 may be stacked on the first semiconductor chip 100. The third surface 200a of the second semiconductor chip 200 may be provided to face the second surface 100b of the first semiconductor chip 100. The third chip pads 201P on the third surface 200a of the second semiconductor chip 200 may be provided to correspond to the second chip pads 102P on the second surface 100b of the first semiconductor chip 100. The second chip pads 102P may be in contact with the third chip pads 201P. In an embodiment, the second chip pads 102P and the third chip pads 201P may form an inter-metal hybrid bonding structure, through a thermocompression process. As a result, the first and second semiconductor chips 100 and 200 may be electrically connected to each other. The second insulating layer 102 of the first semiconductor chip 100 and the third insulating layer 201 of the second semiconductor chip 200 may be in contact with each other. In an embodiment, the second insulating layer 102 and the third insulating layer 201 may form a hybrid bonding structure of oxide, nitride, or oxynitride through a thermocompression process.

The third semiconductor chip 300 may be stacked on the second semiconductor chip 200. The fifth surface 300a of the third semiconductor chip 300 may be provided to correspond to the fourth surface 200b of the second semiconductor chip 200. The fifth chip pads 301P adjacent to the fifth surface 300a of the third semiconductor chip 300 may be provided to correspond to the fourth chip pads 202P adjacent to the fourth surface 200b of the second semiconductor chip 200.

The fourth chip pads 202P and the fifth chip pads 301P may be in contact with each other. In an embodiment, the fourth chip pads 202P and the fifth chip pads 301P may form an inter-metal hybrid bonding structure through a thermocompression process. As a result, the second semiconductor chip 200 and the third semiconductor chip 300 may be electrically connected to each other. The fourth insulating layer 202 of the second semiconductor chip 200 may be in contact with the fifth insulating layer 301 of the third semiconductor chip 300. In an embodiment, the fourth and fifth insulating layers 202 and 301 may form a hybrid bonding structure of oxide, nitride, or oxynitride, through a thermocompression process.

The chip stack CS may be provided in such a way that the first surface 100a of the first semiconductor chip 100 faces the top surface 1000U of the first semiconductor substrate 1000. The first chip pads 101P of the first semiconductor chip 100 may be provided to correspond to the substrate pads 1000P of the first semiconductor substrate 1000. The first insulating layer 101 adjacent to the first surface 100a of the first semiconductor chip 100 may be provided to face the upper insulating layer 1002 adjacent to the top surface 1000U of the first semiconductor substrate 1000.

Referring to FIG. 5, the chip stack CS may be mounted on the first semiconductor substrate 1000, and a thermocompression process may be performed thereon. As a result of the thermocompression process, the substrate pads 1000P on the top surface 1000U of the first semiconductor substrate 1000 may be electrically connected to the first chip pads 101P of the first semiconductor chip 100. The substrate pads 1000P and the first chip pads 101P may form an inter-metal hybrid bonding structure.

As a result of the thermocompression process, the upper insulating layer 1002 adjacent to the top surface 1000U of the first semiconductor substrate 1000 may be in contact with at least a portion of the first insulating layer 101 adjacent to the first surface 100a of the first semiconductor chip 100. The upper insulating layer 1002 and the first insulating layer 101 may form a hybrid bonding structure of oxide, nitride, or oxynitride.

As a result of the thermocompression process, the edge portion of the first semiconductor substrate 1000 may have a warpage structure that is bent toward the bottom surface 1000L of the first semiconductor substrate 1000. The second regions DR of the first semiconductor chip 100 may have a warpage structure that is increasingly spaced apart from the top surface 1000U of the first semiconductor substrate 1000. The first insulating layer 101 adjacent to the second regions DR of the first semiconductor chip 100 may be spaced apart from the top surface 1000U of the first semiconductor substrate 1000 in the first direction D1.

The first semiconductor substrate 1000 may be provided to have a larger size than each of the first to third semiconductor chips 100, 200, and 300 in the chip stack CS. Thus, the degree of warpage of the edge portion of the first semiconductor substrate 1000 may be greater than the degree of warpage of each of the first to the third semiconductor chips 100, 200, and 300. In an embodiment, a separation space between the first semiconductor chip 100 and the first semiconductor substrate 1000 may increase at a position closer to the edge portion of the first semiconductor substrate 1000. A separation space between the corner portion CP of the first semiconductor chip 100 and the top surface 1000U of the first semiconductor substrate 1000 may have the largest volume. The corner portion CP may mean a corner that is defined by two adjacent side surfaces of the first semiconductor chip 100.

A first distance DS between each of the second regions DR and the top surface 1000U in the first direction D1 may increase at a position closer to the edge portion of the first semiconductor substrate 1000. In an embodiment, the first distance DS may be largest at the corner portion CP of the first semiconductor chip 100. In an embodiment, the first distance DS may decrease as a distance to the first region AR decreases.

According to an embodiment, the method of fabricating a semiconductor package may include providing a the mold layer 400 on the top surface 1000U of the first semiconductor substrate 1000 and the chip stack CS. For example, the mold layer 400 may be provided to cover the top surface 1000U of the first semiconductor substrate 1000 and the chip stack CS. The mold layer 400 may be provided to fill a space between each of the second regions DR of the first semiconductor chip 100 and the top surface 1000U of the first semiconductor substrate 1000.

The mold layer 400 may be provided on the side surface of the chip stack CS and on the top surface 1000U of the first semiconductor substrate 1000. For example, the mold layer 400 may be provided to cover the side surface of the chip stack CS and the top surface 1000U of the first semiconductor substrate 1000 and may be extended into a space between each of the second regions DR of the first semiconductor chip 100 and the top surface 1000U of the first semiconductor substrate 1000. The mold layer 400 may be in contact with the first insulating layer 101 on the second regions DR of the first semiconductor chip 100 and may be in contact with the top surface 1000U of the first semiconductor substrate 1000. The mold layer 400 may fill a region between the corner portion CP of the first semiconductor chip 100 and the top surface 1000U of the first semiconductor substrate 1000. The mold layer 400 may be formed of or include at least one of epoxy molding compounds, resins, and polyimide. The mold layer 400 may further include a filler. In an embodiment, the filler may be formed of or include one of silica, alumina, calcium carbonate, and magnesium oxide. However, the disclosure is not limited to thereto.

The average particle diameter of the filler may be less than or equal to 10 μm. In an embodiment, the average particle diameter of the filler may range from 0.5 μm to 3 μm. In an example case in which the average particle diameter of the filler is larger than 3 μm, the mold layer may not fill a region between each of the second regions DR of the first semiconductor chip 100 and the top surface 1000U of the first semiconductor substrate 1000. In an example case in which the average particle diameter of the filler is smaller than 0.5 μm, an agglomeration phenomenon between the fillers may occur. Due to the agglomeration phenomenon, the mold layer may not be uniformly formed.

In an embodiment, the mold layer 400 may fill a region between each of the second regions DR and the first semiconductor substrate 1000. The mold layer 400 may be formed to fill a space between the second regions DR and the first semiconductor substrate 1000, and an empty space (e.g., a void) may not be formed in the space between the second regions DR and the first semiconductor substrate 1000. Thus, due to a difference in thermal expansion coefficient between the empty space and the mold layer 400, it may be possible to prevent the mold layer 400 from being damaged. It may be possible to prevent the mold layer 400 from being damaged by the contraction or expansion caused by heat generated during an operation the semiconductor package. Thus, the structural reliability of the semiconductor package may be improved.

Furthermore, the mold layer 400 may be in contact with the upper insulating layer 1002 of the first semiconductor substrate 1000. The mold layer 400 may be in contact with the upper insulating layer 1002 of the first semiconductor substrate 1000, between each of the second regions DR and the top surface 1000U of the first semiconductor substrate 1000. Thus, the mold layer 400 may prevent the upper insulating layer 1002 from being delaminated by the warpage structure of the first semiconductor substrate 1000. Accordingly, it may be possible to improve the structural reliability of the semiconductor package.

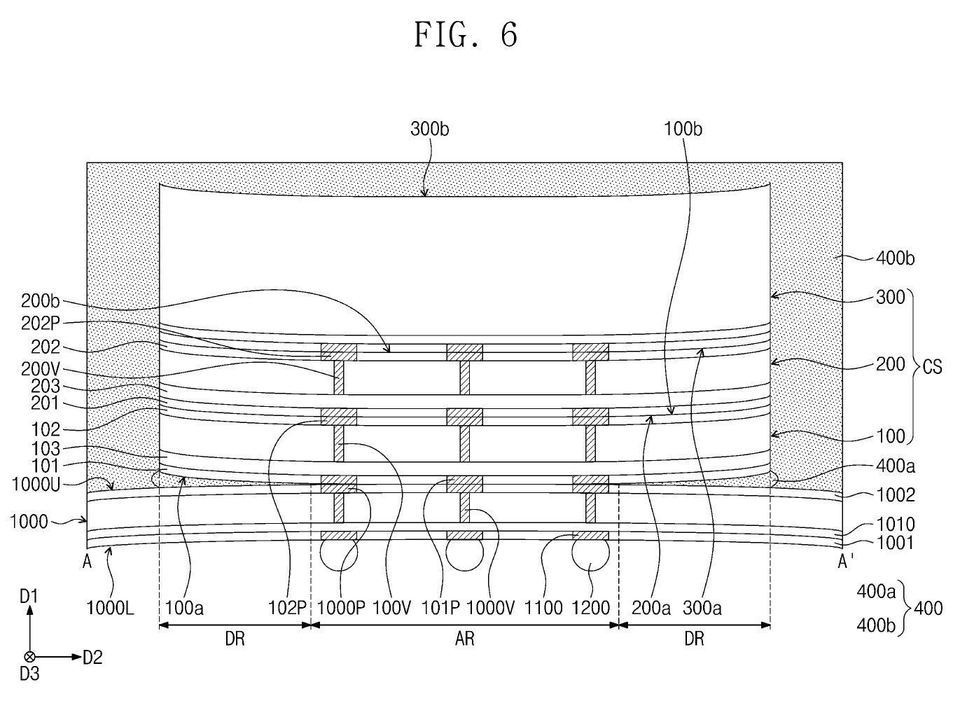

FIG. 6 is a sectional view taken along the line A-A’ of FIG. 1. For concise description, an element previously described with reference to FIGS. 1 to 3 may be identified by the same reference number without repeating an overlapping description thereof.

Referring to FIGS. 1 and 6, the first semiconductor substrate 1000 including the top surface 1000U and the bottom surface 1000L, which are opposite to each other, may be provided. The substrate pads 1000P may be provided to be adjacent to the top surface 1000U of the first semiconductor substrate 1000, and the upper insulating layer 1002 may be extended into a region between the substrate pads 1000P. The edge portion of the first semiconductor substrate 1000 may be bent toward the bottom surface 1000L of the first semiconductor substrate 1000. The first semiconductor substrate 1000 may be deformed in a crying warpage shape.

The chip stack CS may be stacked on the top surface 1000U of the first semiconductor substrate 1000. The lowermost one of the semiconductor chips of the chip stack CS (i.e., the first semiconductor chip 100) may be in contact with the first semiconductor substrate 1000. The first semiconductor chip 100 may include a first surface 100a and a second surface 100b, which are opposite to each other. The first surface 100a may face the top surface 1000U of the first semiconductor substrate 1000.

The first semiconductor chip 100 may include the second regions DR and the first region AR between the second regions DR. The first chip pads 101P may be provided on the first region AR. The first chip pads 101P may be provided adjacent to the first surface 100a. The first chip penetration vias 100V may be provided on the first region AR to penetrate the first semiconductor chip 100 in the first direction D1.

Each of the second regions DR may be spaced apart from the top surface 1000U of the first semiconductor substrate 1000 in the first direction D1. The first semiconductor chip 100 may have a warpage structure in the first direction D1, on the second regions DR. In an embodiment, the first semiconductor chip 100 may have the warpage structure, which is increasingly spaced apart from the top surface 1000U of the first semiconductor substrate 1000 in the first direction D1. A separation distance between each of the second regions DR and the top surface 1000U in the first direction D1 may increase at a position closer to the edge portion of the first semiconductor substrate 1000. In an embodiment, the separation distance may be largest at the corner portion CP of the first semiconductor chip 100. The corner portion CP may be a corner that is defined by two adjacent side surfaces of the first semiconductor chip 100. In an embodiment, the separation space may decrease as a distance to the first region AR decreases.

Referring to FIG. 6, the mold layer 400 may include a first mold layer 400a filling a region between each of the second regions DR of the first semiconductor chip 100 and the top surface 1000U of the first semiconductor substrate 1000. The mold layer 400 may further include a second mold layer 400b provided on the top surface 1000U of the first semiconductor substrate 1000, the chip stack CS, and the first mold layer 400a. For example the second mold layer 400b may be provided to cover the top surface 1000U of the first semiconductor substrate 1000, the chip stack CS, and the first mold layer 400a.

The first mold layer 400a may be extended into a region between each of the second regions DR of the first semiconductor chip 100 and the top surface 1000U of the first semiconductor substrate 1000. The first mold layer 400a may be in contact with the upper insulating layer 1002 of the first semiconductor substrate 1000 and may be in contact with the first insulating layer 101 of the first semiconductor chip 100. The first mold layer 400a may cover the corner portion CP of the first semiconductor chip 100 and the top surface 1000U of the first semiconductor substrate 1000.

The second mold layer 400b may cover the side surface of the chip stack CS and the top surface 1000U of the first semiconductor substrate 1000. The second mold layer 400b may further a side surface of the first mold layer 400a. The second mold layer 400b may be in contact with the upper insulating layer 1002 of the first semiconductor substrate 1000.

The first mold layer 400a may include a first insulating polymer and a first filler. The second mold layer 400b may include a second insulating polymer and a second filler. An average particle diameter of the first filler may be smaller than an average particle diameter of the second filler. The average particle diameter of the first filler may be less than or equal to 10 μm. The average particle diameter of the first filler may range from 0.5 μm to 3 μm. In an embodiment, the average particle diameter of the second filler may range from 4 μm to 10 μm. The first and second fillers may be formed of or include one of silica, alumina, calcium carbonate, and magnesium oxide. However, the disclosure is not limited thereto. In an example case in which the average particle diameter of the first filler is larger than 3 μm, the first mold layer 400a may not fill a space between each of the second regions DR of the first semiconductor chip 100 and the top surface 1000U of the first semiconductor substrate 1000. In an example case in which the average particle diameter of the first filler is smaller than 0.5 μm, an agglomeration phenomenon between the first fillers may occur. Due to the agglomeration phenomenon, the first mold layer 400a may not be uniformly formed. The first and second insulating polymers may be formed of or include the same material. Each of the first and second insulating polymers may be an epoxy resin.

In an embodiment, the first mold layer 400a may not include the first filler. The first mold layer 400a may include the first insulating polymer, and the second mold layer 400b may include the second insulating polymer and the second filler. The first and second insulating polymers may include different materials from each other. The first insulating polymer may include, but is not limited to, at least one of poly imide, polyester, and polyurethane. The second insulating polymer may include, but is not limited to, an epoxy resin.

According to an embodiment of the disclosure, the first mold layer 400a may be provided to fill a region between each of the second regions DR and the first semiconductor substrate 1000. The mold layer 400 may be formed to fill a space between the second regions DR and the first semiconductor substrate 1000, and an empty space (e.g., a void) may not be formed in the space between the second regions DR and the first semiconductor substrate 1000. Thus, due to a difference in thermal expansion coefficient between the empty space and the mold layer 400, it may be possible to prevent the mold layer 400 from being damaged. It may be possible to prevent the mold layer 400 from being damaged by the contraction or expansion caused by heat generated during an operation of the semiconductor package. Thus, the structural reliability of the semiconductor package may be improved.

According to an embodiment, the first mold layer 400a may be in contact with the upper insulating layer 1002 of the first semiconductor substrate 1000. The first mold layer 400a may be in contact with the upper insulating layer 1002 of the first semiconductor substrate 1000, between each of the second regions DR and the top surface 1000U of the first semiconductor substrate 1000. Thus, the first mold layer 400a may prevent the upper insulating layer 1002 from being delaminated by the warpage structure of the first semiconductor substrate 1000. Accordingly, it may be possible to improve the structural reliability of the semiconductor package.

Except for the above features, the semiconductor package illustrated in FIG. 6 may be configured to have substantially the same features as described with reference to FIGS. 1 to 3.

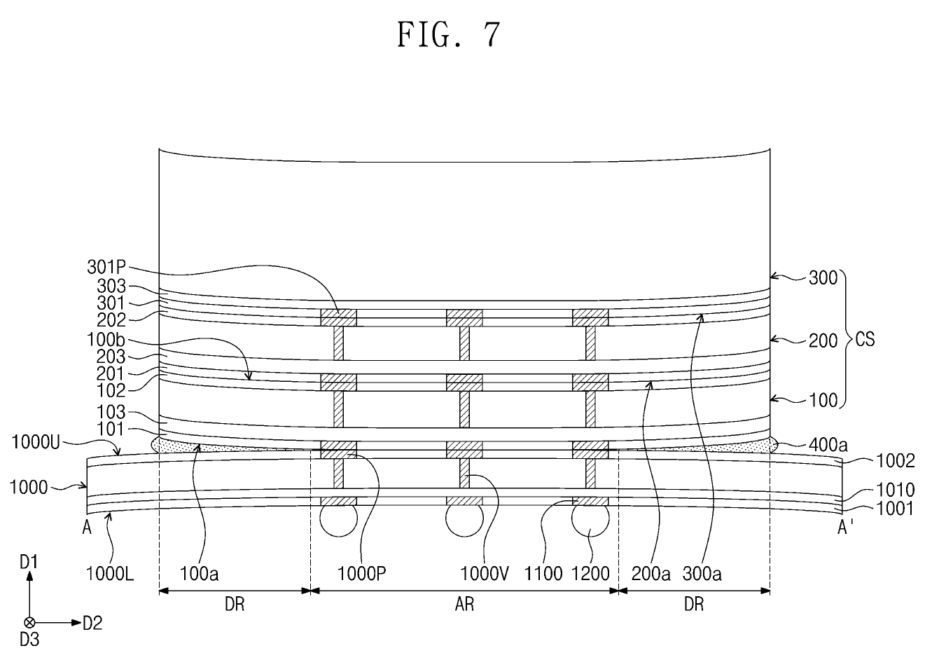

FIG. 7 is a sectional view, which is taken along the line A-A’ of FIG. 1 to illustrate a method of fabricating a semiconductor package, according to an embodiment of the disclosure. For concise description, an element previously described with reference to FIGS. 1 to 3 may be identified by the same reference number without repeating an overlapping description thereof.

Referring back to FIG. 4, the chip stack CS may be provided on the top surface 1000U of the first semiconductor substrate 1000. A plurality of semiconductor chips 100, 200, and 300 in the chip stack CS may be electrically connected to each other. As described with reference to FIG. 4, the semiconductor chips 100, 200, and 300 may be electrically connected to each other through a hybrid bonding structure.

Referring back to FIG. 5, the chip stack CS and the first semiconductor substrate 1000 may be electrically connected to each other. The lowermost semiconductor chip (i.e., the first semiconductor chip 100) of the chip stack CS may be electrically connected to the first semiconductor substrate 1000.

A thermocompression process may be performed to electrically connect the first semiconductor chip 100 to the first semiconductor substrate 1000 through a hybrid bonding structure. As a result of the thermocompression process, the first semiconductor chip 100 may have a warpage structure, on the second regions DR. The second regions DR of the first semiconductor chip 100 may have the warpage structure that is increasingly spaced apart from the top surface 1000U of the first semiconductor substrate 1000 in the first direction D1. The first insulating layer 101 on the second regions DR of the first semiconductor chip 100 may be spaced apart from the top surface 1000U of the first semiconductor substrate 1000 in the first direction D1.

Referring to FIG. 7, the first mold layer 400a may be formed to fill a space between each of the second regions DR of the first semiconductor chip 100 and the top surface 1000U of the first semiconductor substrate 1000. The first mold layer 400a may be extended into a region between each of the second regions DR of the first semiconductor chip 100 and the top surface 1000U of the first semiconductor substrate 1000. The first mold layer 400a may be in contact with the upper insulating layer 1002 of the first semiconductor substrate 1000 and may be in contact with the first insulating layer 101 of the first semiconductor chip 100. The first mold layer 400a may cover the corner portion CP of the first semiconductor chip 100 and the top surface 1000U of the first semiconductor substrate 1000.

In an embodiment, the formation of the first mold layer 400a may include forming a first insulating polymer and a first filler between each of the second regions DR and the top surface 1000U of the first semiconductor substrate 1000 and curing the first insulating polymer. The average particle diameter of the first filler may be less than or equal to 10 μm. In an embodiment, the average particle diameter of the first filler may range from 0.5 μm to 3 μm.

In an example case in which the average particle diameter of the first filler is larger than 3 μm, the first mold layer 400a may not fill a space between each of the second regions DR of the first semiconductor chip 100 and the top surface 1000U of the first semiconductor substrate 1000. In an example case in which the average particle diameter of the first filler is smaller than 0.5 μm, an agglomeration phenomenon between the first fillers may occur. Due to the agglomeration phenomenon, the first mold layer 400a may not be uniformly formed.

According to an embodiment of the disclosure, the first mold layer 400a may not include the first filler. In an embodiment, the formation of the first mold layer 400a may include filling a space between each of the second regions DR and the top surface 1000U of the first semiconductor substrate 1000 with a first insulating polymer and curing the first insulating polymer.

Referring back to FIG. 6, the second mold layer 400b may cover the first mold layer 400a, the chip stack CS, and the first semiconductor substrate 1000. The second mold layer 400b may cover the side surface of the chip stack CS and the top surface 1000U of the first semiconductor substrate 1000. The second mold layer 400b may be in contact with the upper insulating layer 1002 of the first semiconductor substrate 1000.

In an embodiment, the formation of the second mold layer 400b may include forming a second insulating polymer and a second filler to fill a space between the first mold layer 400a and the top surface 1000U of the first semiconductor substrate 1000 and curing the second insulating polymer. The average particle diameter of the second filler may be larger than the average particle diameter of the first filler. The average particle diameter of the second filler may range from 4 μm to 10 μm.

According to an embodiment of the disclosure, the first mold layer 400a may be provided to fill a region between each of the second regions DR and the first semiconductor substrate 1000. The mold layer 400a may be formed to fill a space between the second regions DR and the first semiconductor substrate 1000, such that an empty space (e.g., a void) may not be formed in the space between the second regions DR and the first semiconductor substrate 1000. Thus, due to a difference in thermal expansion coefficient between the empty space and the mold layer 400a, it may be possible to prevent the mold layer 400a from being damaged. It may be possible to prevent the mold layer 400a from being damaged by the contraction or expansion caused by heat generated during an operation of the semiconductor package. Thus, the structural reliability of the semiconductor package may be improved.

In addition, the first mold layer 400a may be in contact with the upper insulating layer 1002 of the first semiconductor substrate 1000. The first mold layer 400a may be in contact with the upper insulating layer 1002 of the first semiconductor substrate 1000, between each of the second regions DR and the top surface 1000U of the first semiconductor substrate 1000. Thus, the first mold layer 400a may prevent the upper insulating layer 1002 from being delaminated by the warpage structure of the first semiconductor substrate 1000. Thus, the semiconductor package with improved structural reliability may be provided.

Except for the above features, the fabrication method illustrated in FIG. 7 may be substantially the same as the fabrication method described with reference to FIGS. 4 and 5.

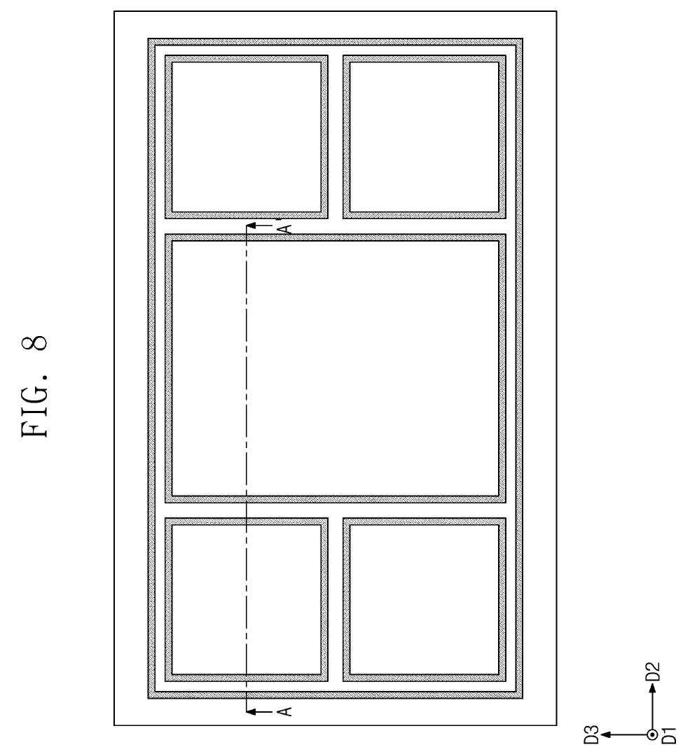

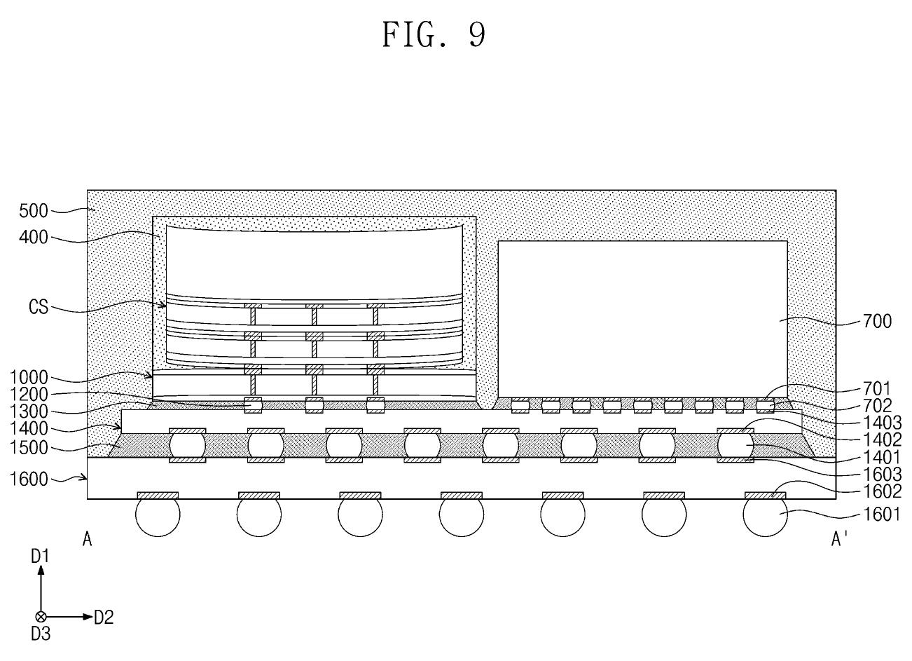

FIG. 8 is a plan view illustrating a semiconductor package according to an embodiment of the disclosure. FIG. 9 is a sectional view taken along a line A-A’ of FIG. 8. For concise description, an element previously described with reference to FIGS. 1 to 3 may be identified by the same reference number without repeating an overlapping description thereof.

Referring to FIGS. 8 and 9, the semiconductor package may include a package substrate 1600, an interposer substrate 1400 on the package substrate 1600, the first semiconductor substrate 1000 on the interposer substrate 1400, a graphic processing unit 700 on the interposer substrate 1400, and the chip stack CS on the first semiconductor substrate 1000.

The package substrate 1600 may be one of a printed circuit board, a semiconductor chip, or a semiconductor package. The package substrate 1600 may include upper connection pads 1603 provided a top surface thereof. The package substrate 1600 may include lower connection pads 1602 provided on a bottom surface of the package substrate 1600. The lower connection pads 1602 may be electrically connected to the upper connection pads 1603 through internal interconnection lines, which are provided in the package substrate 1600. The package substrate 1600 may include lower connection bumps 1601 provided on a bottom surface thereof, and each of the lower connection bumps 1601 may be provided on a corresponding one of the lower connection pads 1602. The lower connection bumps 1601 may be electrically connected to the lower connection pads 1602.

The interposer substrate 1400 may be used for the redistribution of the first semiconductor substrate 1000 and the graphic processing unit 700. The interposer substrate 1400 may be mounted on the package substrate 1600 in a flip chip manner.

The interposer substrate 1400 may include first connection pads 1402 provided a bottom surface interposer substrate 1400. The interposer substrate 1400 may include first connection bumps 1401 provided on a bottom surface thereof. Each of the first connection bumps 1401 may be electrically connected to a corresponding one of the first connection pads 1402. A first under-fill 1500 may be provided between the interposer substrate 1400 and the package substrate 1600. The first under-fill 1500 may cover the first connection bumps 1401.

Second connection pads 1403 may be provided on a top surface of the interposer substrate 1400. The second connection pads 1403 may be electrically connected to the first connection pads 1402 through internal interconnection lines, which are provided in the interposer substrate 1400.

The first semiconductor substrate 1000 may be connected to the interposer substrate 1400 through the outer terminals 1200. The outer terminals 1200 may be electrically connected to the second connection pads 1403 of the interposer substrate 1400.

The first semiconductor substrate 1000 may be configured to have substantially the same features as the first semiconductor substrate 1000 described with reference to FIGS. 1 to 3. The chip stack CS may be configured to have substantially the same features as the chip stack CS described with reference to FIGS. 1 to 3.

As described with reference to FIGS. 1 to 3, each of the second regions DR of the lowermost semiconductor chip (i.e., the first semiconductor chip 100) of the chip stack CS may be spaced apart from the top surface 1000U of the first semiconductor substrate 1000 in the first direction D1.

An inner mold layer 400 may cover the chip stack CS and the top surface of the first semiconductor substrate 1000. The inner mold layer 400 may be the mold layer 400 described with reference to FIGS. 1 to 3. The inner mold layer 400 may be provided to fill a space between the top surface of the first semiconductor substrate 1000 and each of the second regions DR of the first semiconductor chip 100, as described with reference to FIGS. 1 to 3.

The graphic processing unit 700 may be provided on the interposer substrate 1400. The graphic processing unit 700 may be spaced apart from the first semiconductor substrate 1000 in the second direction D2. A thickness of the graphic processing unit 700 may be thicker than a thickness of each of the semiconductor chips of the chip stack CS. In an embodiment, the graphic processing unit 700 may be a logic chip. Bumps 702 may be provided on a bottom surface of the graphic processing unit 700. The graphic processing unit 700 may be electrically connected to the interposer substrate 1400 through the bumps 702. A second under-fill 1300 may be provided between the interposer substrate 1400 and the graphic processing unit 700. The under-fill layer may fill a space between the interposer substrate 1400 and the graphic processing unit 700 and may conformally cover the bumps 702.

An outer mold layer 500 may be provided on the interposer substrate 1400. The outer mold layer 500 may be further provided on the inner mold layer 400 and the graphic processing unit 700. For example, the outer mold layer 500 may cover the inner mold layer 400 and the graphic processing unit 700. The outer mold layer 500 may include an insulating resin (e.g., an epoxy molding compound (EMC)).

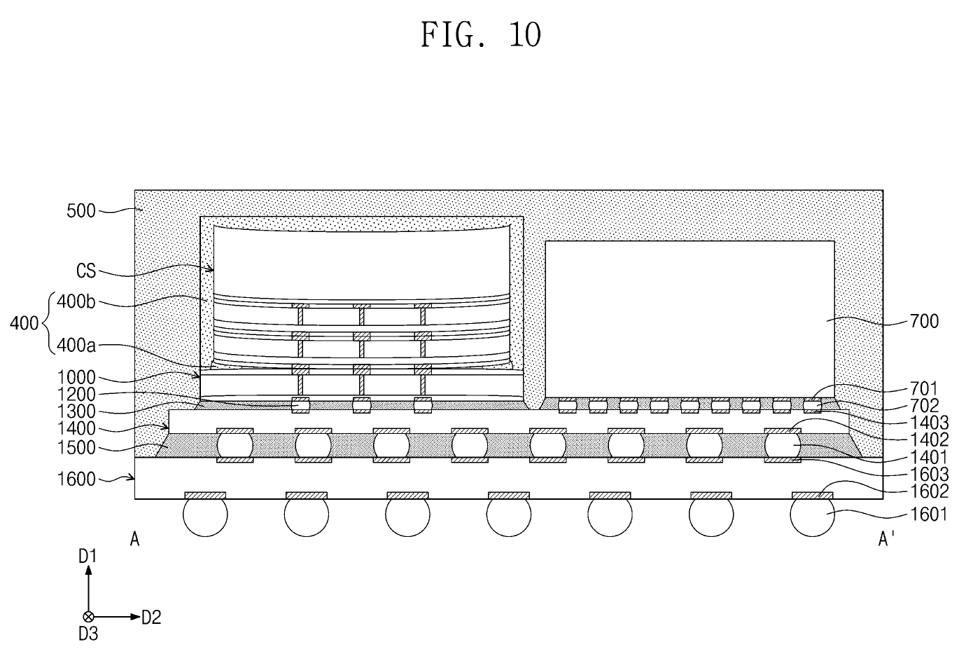

FIG. 10 is a sectional view illustrating a semiconductor package according to an embodiment of the disclosure, taken along the line A-A’ of FIG. 8. For concise description, an element previously described with reference to FIGS. 1 to 3 may be identified by the same reference number without repeating an overlapping description thereof.

The semiconductor package may include the package substrate 1600, the interposer substrate 1400 on the package substrate 1600, the first semiconductor substrate 1000 on the interposer substrate 1400, the graphic processing unit 700 on the interposer substrate 1400, and the chip stack CS on the first semiconductor substrate 1000.

The package substrate 1600 may be one of a printed circuit board, a semiconductor chip, or a semiconductor package. The package substrate 1600 may include the upper connection pads 1603 provided on a top surface thereof. The package substrate 1600 may include lower connection pads 1602 provided on a bottom surface thereof. The lower connection pads 1602 may be electrically connected to the upper connection pads 1603 through internal interconnection lines, which are provided in the package substrate 1600. The package substrate 1600 may include the lower connection bumps 1601 provided on a bottom surface thereof, and each of the lower connection bumps 1601 may be provided on a corresponding one of the lower connection pads 1602. The lower connection bumps 1601 may be electrically connected to the lower connection pads 1602.

The interposer substrate 1400 may be used for the redistribution of the first semiconductor substrate 1000 and the graphic processing unit 700. The interposer substrate 1400 may be mounted on the package substrate 1600 in a flip chip manner.

The interposer substrate 1400 may include first connection pads 1402 provided on a bottom surface thereof. The interposer substrate 1400 may include the first connection bumps 1401 provided on a bottom surface thereof. Each of the first connection bumps 1401 may be electrically connected to a corresponding one of the first connection pads 1402. The first under-fill 1500 may be provided between the interposer substrate 1400 and the package substrate 1600. The first under-fill 1500 may cover the first connection bumps 1401. The second connection pads 1403 may be provided on a top surface of the interposer substrate 1400. The second connection pads 1403 may be electrically connected to the first connection pads 1402 through internal interconnection lines, which are provided in the interposer substrate 1400.

The first semiconductor substrate 1000 may be connected to the interposer substrate 1400 through the outer terminals 1200. The outer terminals 1200 may be electrically connected to the second connection pads 1403 of the interposer substrate.

The first semiconductor substrate 1000 may be the first semiconductor substrate 1000 described with reference to FIGS. 1 to 3. The chip stack CS may be the chip stack CS described with reference to FIGS. 1 to 3.

As described with reference to FIGS. 1 to 3, each of the second regions DR of the lowermost semiconductor chip (i.e., the first semiconductor chip 100) of the chip stack CS may be spaced apart from the top surface of the first semiconductor substrate 1000 in the first direction D1.

The inner mold layer 400 may cover the chip stack CS and the top surface of the first semiconductor substrate 1000. The inner mold layer 400 may be the mold layer described with reference to FIGS. 1 and 6. The first mold layer 400a may be provided to fill a space between the top surface of the first semiconductor substrate 1000 and each of the second regions DR of the first semiconductor chip 100, as described with reference to FIGS. 1 and 6. The second mold layer 400b may cover the first mold layer 400a and the top surface of the first semiconductor substrate 1000.

The graphic processing unit 700 may be provided on the interposer substrate 1400. The graphic processing unit 700 may be spaced apart from the first semiconductor substrate 1000 in the second direction D2. A thickness of the graphic processing unit 700 may be larger than a thickness of each of the semiconductor chips of the chip stack CS. In an embodiment, the graphic processing unit 700 may be a logic chip. Bumps may be provided on a bottom surface of the graphic processing unit 700. The graphic processing unit 700 may be electrically connected to the interposer substrate 1400 through the bumps. An under-fill layer may be provided between the interposer substrate 1400 and the graphic processing unit 700. The under-fill layer may fill a space between the interposer substrate 1400 and the graphic processing unit 700 and may conformally cover the bumps.

The outer mold layer 500 may be provided on the interposer substrate 1400. The outer mold layer 500 may cover the inner mold layer 400 and the graphic processing unit 700. The outer mold layer 500 may include an insulating resin (e.g., an epoxy molding compound (EMC)).

According to an embodiment of the disclosure, the lowermost semiconductor chip (e.g., a first semiconductor chip) of the chip stack may include first regions and second regions. Each of the second regions may be spaced apart from a top surface of the first semiconductor substrate. A mold layer may be provided to fill a space between each of the second regions and the first semiconductor substrate. The mold layer may be formed to fill a space between the second regions and the first semiconductor substrate, and an empty space (e.g., a void) may not be formed in the space between the second regions and the first semiconductor substrate. Thus, due to a difference in thermal expansion coefficient between the empty space and the mold layer, it may be possible to prevent the mold layer from being damaged. It may be possible to prevent the mold layer 400 from being damaged by the contraction or expansion caused by heat generated during an operation of the semiconductor package. Thus, the structural reliability of the semiconductor package may be improved.

Furthermore, the mold layer may be in contact with an upper insulating layer of the first semiconductor substrate. The mold layer may be in contact with the upper insulating layer of the first semiconductor substrate, between each of the second regions and the top surface of the first semiconductor substrate. Thus, the mold layer may prevent the upper insulating layer from being delaminated by a warpage structure of the first semiconductor substrate. Accordingly, it may be possible to improve the structural reliability of the semiconductor package.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first semiconductor substrate comprising a top surface and a bottom surface;
a chip stack stacked on the top surface of the first semiconductor substrate, the chip stack comprising a plurality of semiconductor chips; and
a mold layer provided on the top surface of the first semiconductor substrate and on the chip stack,
wherein a first semiconductor chip, among the plurality of semiconductor chips, comprises:
a first region provided with a plurality of chip pads; and
a plurality of second regions provided at a first side and a second side of the first region,
wherein each of the plurality of chip pads of the first semiconductor chip is bonded to one of a plurality of substrate pads of the first semiconductor substrate,
the plurality of chip pads and the plurality of substrate pads are formed of a same metallic material to form a single object,
each of the plurality of second regions of the first semiconductor chip is spaced apart from the top surface of the first semiconductor substrate in a first direction perpendicular to the top surface of the first semiconductor substrate, and
the mold layer fills a space between each of the plurality of second regions and the top surface of the first semiconductor substrate.

2. The semiconductor package of claim 1, wherein the mold layer comprises a filler, and
an average particle diameter of the filler ranges from 0.5 μm to 3 μm.

3. The semiconductor package of claim 1, wherein the mold layer comprises one of epoxy molding compounds, resins, and polyimide.

4. The semiconductor package of claim 1, wherein the mold layer comprises:
a first mold layer filling a space between each of the plurality of second regions and the top surface of the first semiconductor substrate; and
a second mold layer provided on the top surface of the first semiconductor substrate, the chip stack and the first mold layer,
wherein the first mold layer comprises a first material and the second mold layer comprises a second material different from the first material.

5. The semiconductor package of claim 1, wherein the mold layer comprises:
a first mold layer filling a space between each of the plurality of second regions and the top surface of the first semiconductor substrate, the first mold layer comprising a first filler; and
a second mold layer provided on the top surface of the first semiconductor substrate, the chip stack, and the first mold layer, the second mold layer comprising a second filler,
wherein an average particle diameter of the first filler is smaller than an average particle diameter of the second filler.

6. The semiconductor package of claim 1, wherein the first semiconductor chip has a first surface and a second surface,
the first surface of the first semiconductor chip faces the top surface of the first semiconductor substrate,
the plurality of chip pads of the first semiconductor chip are provided to be adjacent to the first surface,
the first semiconductor chip comprises a first insulating layer, which is provided to be adjacent to the first surface and is extended into a region between the plurality of chip pads,
the plurality of substrate pads of the first semiconductor substrate are provided to be adjacent to the top surface,
the first semiconductor substrate comprises an upper insulating layer, which is provided to be adjacent to the top surface and is extended into a region between the plurality of substrate pads, and
the first insulating layer comprises the same material as the upper insulating layer.

7. The semiconductor package of claim 6, wherein the first insulating layer on the first region of the first semiconductor chip is in contact with the upper insulating layer of the first semiconductor substrate.

8. The semiconductor package of claim 1, further comprising:
a via provided in the first semiconductor substrate,
wherein the via is electrically connected to a corresponding one of the plurality of substrate pads.

9. The semiconductor package of claim 1, wherein the first semiconductor chip comprises a chip via provided in the first semiconductor chip,
the chip via is provided on the first region, and
the chip via is electrically connected to a corresponding one of the plurality of chip pads.

10. The semiconductor package of claim 1, wherein the mold layer is provided on a side surface of the chip stack and on a the top surface of the first semiconductor substrate, and the mold layer extends into a space between each of the plurality of second regions of the first semiconductor chip and the top surface of the first semiconductor substrate.

11. A semiconductor package, comprising:
a first semiconductor substrate comprising a top surface and a bottom surface;
a chip stack stacked on the top surface of the first semiconductor substrate, the chip stack comprising a plurality of semiconductor chips; and
a mold layer provided on the first semiconductor substrate and on the chip stack,
wherein a first semiconductor chip, among the plurality of semiconductor chips, comprises:
a first region provided with a plurality of chip pads; and
a plurality of second regions provided at a first side and a second side of the first region,
wherein each of the plurality of chip pads of the first semiconductor chip is bonded to one of a plurality of substrate pads of the first semiconductor substrate,
the plurality of chip pads and the plurality of substrate pads are formed of a same metallic material to form a single object,
each of the plurality of second regions of the first semiconductor chip is spaced apart from the top surface of the first semiconductor substrate in a first direction perpendicular to the top surface of the first semiconductor substrate,
wherein the mold layer comprises:
a first mold layer filling a space between each of the plurality of second regions and the top surface of the first semiconductor substrate; and
a second mold layer provided on the top surface of the first semiconductor substrate, the chip stack, and the first mold layer.

12. The semiconductor package of claim 11, wherein the first semiconductor chip has a first surface and a second surface,
the first surface of the first semiconductor chip faces the top surface of the first semiconductor substrate,
the plurality of chip pads of the first semiconductor chip are provided to be adjacent to the first surface,
the first semiconductor chip comprises a first insulating layer, which is provided to be adjacent to the first surface and is extended into a region between the plurality of chip pads,
the plurality of substrate pads of the first semiconductor substrate are provided to be adjacent to the top surface of the first semiconductor substrate,
the first semiconductor substrate comprises an upper insulating layer, which is provided to be adjacent to the top surface and is extended into a region between the plurality of substrate pads, and
at least a portion of the first insulating layer is in contact with the upper insulating layer of the first semiconductor substrate.

13. The semiconductor package of claim 12, wherein the first mold layer is in contact with the first insulating layer on the plurality of second regions and is in contact with the upper insulating layer on the top surface of the first semiconductor substrate.

14. The semiconductor package of claim 12, wherein the first insulating layer on the first region of the first semiconductor chip is in contact with the upper insulating layer of the first semiconductor substrate.

15. The semiconductor package of claim 12, wherein the first insulating layer on the plurality of second regions of the first semiconductor chip is spaced apart from the upper insulating layer of the first semiconductor substrate in the first direction.

16. The semiconductor package of claim 11, further comprising:
a chip via in the first semiconductor chip,
wherein the chip via is provided on the first region, and
the chip via is electrically connected to a corresponding one of the plurality of chip pads.

17. A semiconductor package, comprising:
a package substrate;
an interposer substrate on the package substrate;
a first semiconductor substrate provided on the interposer substrate, the first semiconductor substrate comprising a top surface and a bottom surface;
a chip stack stacked on the top surface of the first semiconductor substrate, the chip stack comprising a plurality of semiconductor chips; and
a mold layer provided on the top surface of the first semiconductor substrate and on the chip stack,
wherein a first semiconductor chip, among the plurality of semiconductor chips:
a first region provided with a plurality of chip pads; and
a plurality of second regions provided at a first side and a second side of the first region,
wherein each of the plurality of chip pads of the first semiconductor chip is bonded to one of a plurality of substrate pads of the first semiconductor substrate,
the plurality of chip pads and the plurality of substrate pads are formed of a same metallic material to form a single object,
each of the plurality of second regions of the first semiconductor chip is spaced apart from the top surface of the first semiconductor substrate in a first direction perpendicular to the top surface of the first semiconductor substrate, and
the mold layer fills a space between each of the plurality of second regions and the top surface of the first semiconductor substrate.

18. The semiconductor package of claim 17, wherein the first semiconductor chip has a first surface and a second surface,
the first surface of the first semiconductor chip faces the top surface of the first semiconductor substrate,
the plurality of chip pads of the first semiconductor chip are provided to be adjacent to the first surface,
the first semiconductor chip comprises a first insulating layer, which is provided to be adjacent to the first surface and is extended into a region between the plurality of chip pads,
the plurality of substrate pads of the first semiconductor substrate are provided to be adjacent to the top surface of the first semiconductor substrate,
the first semiconductor substrate comprises an upper insulating layer, which is provided to be adjacent to the top surface and is extended into a region between the plurality of substrate pads, and
at least a portion of the first insulating layer is in contact with the upper insulating layer of the first semiconductor substrate.

19. The semiconductor package of claim 17, wherein the mold layer comprises:
a first mold layer filling a space between each of the plurality of second regions and the top surface of the first semiconductor substrate; and
a second mold layer provided on the top surface of the first semiconductor substrate, the chip stack and the first mold layer,
wherein the first mold layer comprises a first material and the second mold layer comprises a second material different from the first material.

20. The semiconductor package of claim 17, wherein the mold layer comprises:
a first mold layer filling a space between each of the plurality of second regions and the top surface of the first semiconductor substrate, the first mold layer comprising a first filler; and
a second mold layer provided on the top surface of the first semiconductor substrate, the chip stack, and the first mold layer, the second mold layer comprising a second filler,
wherein an average particle diameter of the first filler is smaller than an average particle diameter of the second filler.
